(19) United States
(12) Patent Application Publication
(10) Pub. No.: US 2017/0068772 A1
(43) Pub. Date: Mar. 9, 2017

(54) SYSTEM FOR OPTIMIZING POWER LEAKAGE AND TIMING DELAY IN AN INTEGRATED CIRCUIT BASED ON A COST FACTOR OF REPLACING CELLS

(71) Applicant: QUALCOMM Incorporated, San Diego, CA (US)

(72) Inventors: Kelageri NAGARAJ, San Diego, CA (US); Paras GUPTA, San Diego, CA (US); Thomas YU, San Diego, CA (US); Venkatesh NAYAK, San Diego, CA (US); Anil Kumar KODURU, San Diego, CA (US); Bhanuprakash GANGULA VENKATARAMA REDDY, San Diego, CA (US)

(21) Appl. No.: 15/258,923

(22) Filed: Sep. 7, 2016

Related U.S. Application Data
(60) Provisional application No. 62/215,616, filed on Sep. 8, 2015.

(51) Int. Cl. G06F 17/50; H03K 5/13; H03K 19/00

(52) U.S. Cl. CPC G06F 17/5081; H03K 19/0008; H03K 5/13; H03K 2005/00019

(57) ABSTRACT

A method of and an apparatus for optimizing timing delay and power leakage in a circuit. The apparatus determines at least one path of a plurality of paths in a network of logic elements, the at least one path including a plurality of cells, each of the cells being configured to perform a logical operation. In addition, the apparatus identifies a first cell of the plurality of cells based on a first cost factor associated with replacing the first cell with a first replacement cell that performs the same logical operation, the first cost factor being a function of a power leakage difference and a timing delay difference associated with the first cell and the first replacement cell. Furthermore, the apparatus replaces the first cell with the first replacement cell in the at least one path.

### CROSS-REFERENCE TO RELATED APPLICATION(S)

This application claims the benefit of U.S. Provisional Application Ser. No. 62/215,616, entitled “SYSTEM FOR OPTIMIZING POWER LEAKAGE AND TIMING DELAY IN AN INTEGRATED CIRCUIT BASED ON A COST FACTOR OF REPLACING CELLS” and filed on Sep. 8, 2015, which is expressly incorporated by reference herein in its entirety.

### BACKGROUND

Field

The present disclosure relates generally to integrated circuits (ICs), and more particularly, to systems for optimizing power leakage and timing delay in ICs based on a cost factor of replacing cells.

Background

In synthesis electronic design analysis (EDA) tools, a design is normally mapped to a set of logical cells, placed, and routed, all while attempting to meet number of design constraints. Timing is one of the more important design constraints. Without meeting the setup and hold time constraints, a design will not operate reliably under particular timing specifications. As a result, other design constraints, such as area and power, are often not efficiently improved, since timing receives most of the focus in such systems. With scaling technologies often below a 100 nm minimum feature size, power leakage is becoming an increasing problem in modern integrated circuit (IC) designs.

Thus, the need arises for a solution that effectively optimizes power leakage while addressing timing constraints.

### SUMMARY

The following presents a simplified summary of one or more aspects in order to provide a basic understanding of such aspects. This summary is not an extensive overview of all contemplated aspects, and is intended to neither identify key or critical elements of all aspects nor delineate the scope of any or all aspects. Its sole purpose is to present some concepts of one or more aspects in a simplified form as a prelude to the more detailed description that is presented later.

In an aspect of the disclosure, an apparatus for optimizing timing delay and power leakage in a circuit is provided. The apparatus may be tool (e.g., synthesis tool) for translating an integrated circuit (IC) design to a set of logical cells. The apparatus is configured to determine at least one path of a plurality of paths in a network of logic elements, the at least one path including a plurality of cells, each of the cells being configured to perform a logical operation. In addition, the apparatus is configured to identify a first cell of the plurality of cells based on a first cost factor associated with replacing the first cell with a first replacement cell that performs the same logical operation, the first cost factor being a function of a power leakage difference and a timing delay difference associated with the first cell and the first replacement cell. Furthermore, the apparatus is configured to replace the first cell with the first replacement cell in the at least one path.

### BRIEF DESCRIPTION OF THE DRAWINGS

The disclosed aspects will hereinafter be described in conjunction with the appended drawings, provided to illustrate and not to limit the disclosed aspects, wherein like designations denote like elements, and in which:

FIG. 1 is a diagram conceptually illustrating an example apparatus configured for optimizing power leakage and timing delay in ICs based on a cost factor of replacing cells.

FIG. 2 is a diagram conceptually illustrating a plurality of paths including cells between memory stages.

FIG. 3 is a flow diagram conceptually illustrating an example of a method of optimizing power leakage and timing delay in ICs based on a cost factor of replacing cells.

FIG. 4 is a flowchart conceptually illustrating an example of a method of optimizing power leakage and timing delay in ICs based on a cost factor of replacing cells.

FIG. 5 is a diagram conceptually illustrating an example of a hardware implementation for an apparatus employing a processing system configured for optimizing power leakage and timing delay in ICs based on a cost factor of replacing cells.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known structures and components are shown in block diagram form in order to avoid obscuring such concepts. Apparatuses and methods will be described in the following detailed description and may be illustrated in the accompanying drawings by various blocks, modules, components, circuits, steps, processes, algorithms, elements, etc. Moreover, the term “component” as used herein may be one of the parts that make up a system, may be hardware or software or some combination thereof, and may be divided into other components.

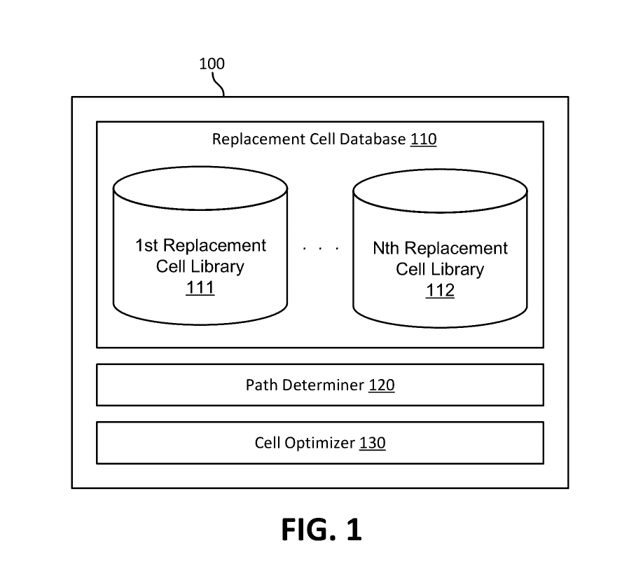

FIG. 1 is a diagram conceptually illustrating an example apparatus 100 configured for optimizing power leakage and timing delay in integrated circuits (ICs) based on a cost factor of replacing cells. The apparatus may be a synthesis tool that is configured to translate an IC design to a set of logical cells (e.g., logic gates) that provide a Boolean logic function (e.g. AND, OR, XOR, inversion, etc.).

In an aspect, the apparatus 100 may include a replacement cell database 110, which may include a plurality of replacement cell libraries for each type of cell in the IC, such as libraries 111 and 112. Each replacement cell library may include a plurality of replacement cells that are configured to provide the same logical operation as a respective one of the cells in the translated IC design. The plurality of replacement cells in each library differ from one another based on at least one or a combination of a level of doping of a channel, a length of the channel, and a width of the channel. These differences result in a range of cells that vary in power leakage and timing delay.

For example, the first replacement cell library 111 may include six type A replacement cells A1, A2, A3, A4, A5, A6. Cells A1, A2, A3 may have a first level of channel doping, and cells A4, A5, A6 may have a second level of channel doping that results in cells A1, A2, A3 having a higher threshold voltage, being faster, and leaking more power than cells A4, A5, A6. Furthermore, replacement cells A1, A2, A3 may differ from one another in channel length. For example, cell A1 may have a channel length of 20 nm, cell A2 may have a channel length of 22 nm, and cell A3 may have a channel length of 24 nm. Replacement cells A4, A5, A6 may likewise differ from one another in channel length. For example, cell A4 may have a channel length of 20 nm, cell A5 may have a channel length of 22 nm, and cell A6 may have a channel length of 24 nm. Cells with shorter channel lengths are faster and have a greater power leakage than cells with longer channel lengths. The differences between the various type A replacement cells allows for a wide range of cells that vary in timing delay and power leakage. In an aspect, type A replacement cells A1, A2, A3, A4, A5, A6 may have the timing delay and power leakage values shown below in Table 1.

TABLE 1

| Cell | Power Leakage (mW) | Timing Delay (ps) |
|---|---|---|
| A1 | 100 | 20 |
| A2 | 60 | 21 |
| A3 | 36 | 23 |
| A4 | 20 | 26 |
| A5 | 15 | 32 |
| A6 | 12 | 45 |

In an aspect, as shown in Table 1, the replacement cells may be ranked from 1 to n in order from highest to lowest power leakage or lowest to highest timing delay.

As another example, a second replacement cell library (not shown) may include six type B replacement cells B1, B2, B3, B4, B5, B6. Each of the type B replacement cells may differ from one another in a manner similar to the type A replacement cells, and thus also provide a wide range of cells that vary in timing delay and power leakage. In an aspect, type B replacement cells may have the timing delay and power leakage values shown below in Table 2.

TABLE 2

| Cell | Power Leakage (mW) | Timing Delay (ps) |
|---|---|---|
| B1 | 1000 | 22 |
| B2 | 600 | 23.1 |
| B3 | 360 | 25.3 |
| B4 | 200 | 28.6 |
| B5 | 150 | 35.2 |
| B6 | 120 | 49.5 |

Each of the replacement cells may also have a cost factor associated with replacing the replacement cell with another replacement cell in the replacement cell library. The cost factor may be based on a timing delay difference and a power leakage difference between two of the same type of replacement cells. For example, a first replacement cell may have a power leakage p1 and a timing delay d1, and a second replacement cell may have a power leakage p2 and a timing delay d2. The cost factor for replacing the first replacement cell with the second replacement cell is c1, where c1=|d1−d2|/|p1−p2|.

If the timing delay of the second replacement cell is greater than the timing delay of the first replacement cell (i.e., d2>d1) and the power leakage of the second replacement cell is less than the power leakage of the first replacement cell (i.e., p2<p1), then substituting the first replacement cell with the second replacement cell would result in a greater timing delay and a lower power leakage. Thus, the cost factor for substituting the first replacement cell with the second replacement cell is identified as an increase in timing delay per decrease in power leakage.

Conversely, if the timing delay of the second replacement cell is less than the timing delay of the first replacement cell (i.e., d2<d1) and the power leakage of the second replacement cell is greater than the power leakage of the first replacement cell (i.e., p2>p1), then substituting the first replacement cell with a second replacement cell would result in a shorter timing delay and a greater power leakage. Thus, the cost factor for substituting the first replacement cell with the second replacement cell is identified as a decrease in timing delay per increase in power leakage.

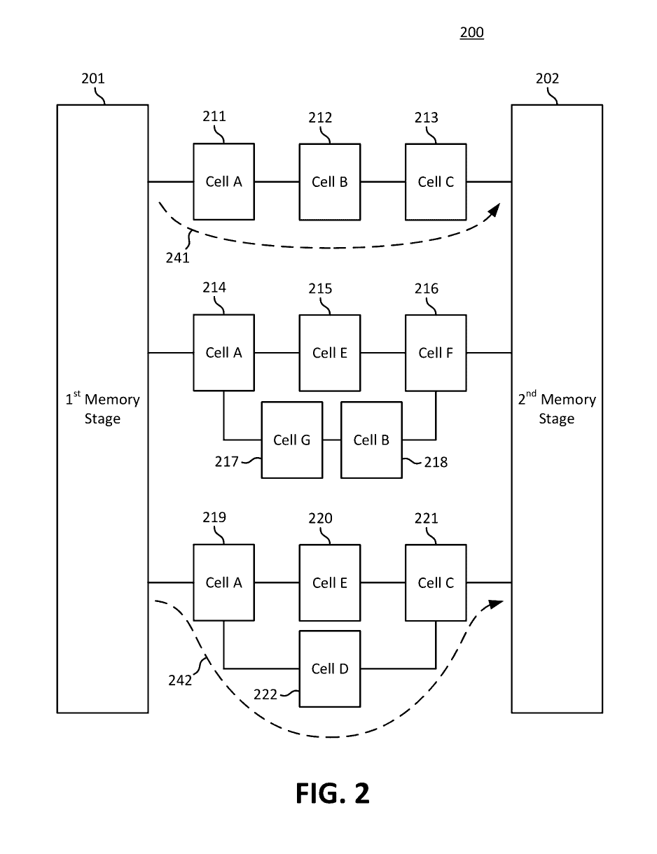

In an aspect, the apparatus 100 may include a path determiner 120 and a cell optimizer 130. The path determiner 120 may analyze a network of a plurality of cells and determine timing paths through the plurality of cells. This aspect is explained below with reference to FIG. 2.

FIG. 2 is a diagram conceptually illustrating a circuit 200 including cells between memory stages. As shown in FIG. 2, the circuit may include a first memory stage 201 and a second memory stage 202, each of which may be a memory, a register (e.g., flip-flop, latch), or any other element that may store data. The path determiner 120 may identify a network of logic elements, such as cells 211-222, between the first and second memory stages 201, 202. The cells 211-222 may be different type of cells that perform different logical functions (e.g. AND, OR, XOR, inversion, etc.). For example, cells 211, 214, 219 may be type A cells; cells 212, 218 may be a type B cells; cells 213, 221 may be type C cells; cell 222 may be a type D cell; cells 215, 220 may be type E cells; cell 216 may be a type F cell; and cell 217 may be a type G cell. The path determiner may then determine timing paths between memory stages 201, 202. For example, the path determiner 120 may determine that cells 211, 212, 213 constitute a first timing path 241 between the first memory stage 201 and the second memory stage 202. As another example, the path determiner 120 may determine that cells 219, 222, 221 constitute a second timing path 242 between the first memory stage 201 and the second memory stage 202.

The path determiner 120 may then determine a timing of the paths. For example, the path determiner 120 may measure a propagation time of a signal through each path and determine whether the propagation time meets a timing criteria by comparing the propagation time to a time threshold. If the propagation time meets the timing criteria (i.e., propagation time is less than or equal to a time threshold), then the path determiner 120 may determine that the path includes a positive timing slack. If, however, the propagation time does not meet the timing criteria (i.e., propagation time is greater than the time threshold), then the path determiner 120 may determine that the path includes a timing violation.

In either case, whether a path meets or does not meet a timing criteria, the cell optimizer 130 may configure the cells on the path such that the path offers optimal balance between timing delay and power leakage.

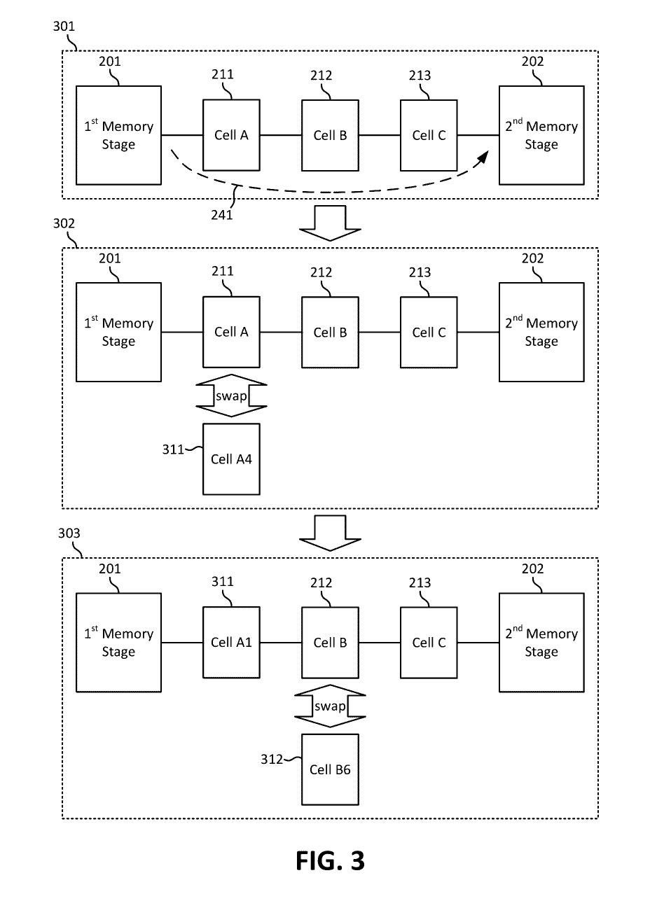

FIG. 3 is a flow diagram conceptually illustrating an example of a method of optimizing power leakage and timing delay in ICs based on a cost factor of replacing cells. For example, as shown in block 301 of FIG. 3, the cell optimizer 130 may analyze path 241 in view of the path timing as determined by the path determiner 120.

In an aspect, if the timing of path 241 is determined to have a positive timing slack, the cell optimizer 130 may determine a timing delay and power leakage associated with each of the cells 211, 212, 213 on path 241 to determine a cost factor associated with replacing each of the cells 211, 212, 213 with a respective replacement cell from replacement cell database 110. The cell optimizer 130 may likewise determine a timing delay and power leakage associated with each of the replacement cells in each of the replacement cell libraries 111, 112 associated with each of the cells 211, 212, 213.

In an aspect, each of the cells 211, 212, 213 has an equivalent cell among the plurality of corresponding replacement cells, and the equivalent cell includes the same timing delay and power leakage as one of the respective cells 211, 212, 213. For example, cell A 211 may correspond to equivalent replacement cell A3 in Table 1, and cell B 212 may correspond to equivalent replacement cell B5 in Table 2.

The cell optimizer 130 may then determine the cost factor based on a ratio of a timing delay difference and a power leakage difference between each of the cells 211, 212, 213 and a corresponding one of the replacement cells. Because the path 241 includes a positive timing slack, the cell optimizer may search for a first cell among the cells 211, 212, 213 that, when substituted with a replacement cell in path 241, will provide path 241 with a lowest increase in timing delay per decrease in power leakage.

For example, as an initial mater, the cell optimizer 130 may analyze each of the cells 211, 212, 213 individually with respect to each of their corresponding replacement cells, and determine which replacement cell would provide the lowest increase in timing delay per decrease in power leakage from among the replacement cells for each respective one of the cells 211, 212, 213.

For example, as shown in 301 of FIG. 3, cell optimizer 130 may determine that cell A 211 is equivalent to replacement cell A3, and that substituting cell A 211 with replacement cell A4 would result in a lowest increase in timing delay per decrease in power leakage from among the cell A replacement cells. The cost factor for replacing cell A 211 with cell A4 may be 0.188.

As previously described, the cost factor is a ratio of the difference in delay times to the difference in power leakage of two cells (i.e., c1=|d1−d2|/|p1−p2|). In this case, cell A 211 (i.e., replacement cell A3) may have a power leakage p1=36 and a timing delay d1=23, and replacement cell A4 may have a power leakage p2=20 and a timing delay d2=26. As such, the cost factor for substituting cell A 211 with replacement cell A4 is c1=|d1−d2|/|p1−p2|=|23−26|/|36−20|=0.188.

The cell optimizer 130 may also determine that the cost factor for substituting cell A 211 with a replacement cell other than A3 will either decrease timing delay and reduce power leakage (e.g., replacing cell A 211 with either one of replacement cells A1 or A2), or result in a cost factor that would not provide the lowest increase in timing delay per decrease in power leakage (e.g., replacing cell A 211 with either one of replacement cells A5 or A6).

Moving on to cell B 212, the cell optimizer 130 may, for example, determine that cell B 212 is equivalent to replacement cell B5, and that substituting cell B 212 with replacement cell B6 would result in a lowest increase in timing delay per decrease in power leakage from among the cell B replacement cells. The cost factor for replacing cell B 212 with replacement cell B6 may be 0.477.

When analyzing cell C 213, the cell optimizer 130 may, for example, determine that cell C 213 is equivalent to replacement cell C2, and that substituting cell C 213 with replacement cell C3 would result in a lowest increase in timing delay per decrease in power leakage from among the cell B replacement cells. The cost factor for replacing cell C 213 with replacement cell C3 may be 0.725.

Once the cell optimizer 130 determines the most effective cost factor for each respective one of the cells 211, 212, 213, the cell optimizer may compare the cost factors, and select the cell associated with the cost factor having a lowest increase in timing delay per decrease in power leakage from among the cost factors associated with the cells 211, 212, 213. For example, the cell optimizer 130 may determine that the cost factor with the lowest increase in timing delay per decrease in power leakage is the cost factor (e.g., 0.188) associated with replacing cell A 211 with replacement cell A4.

As shown in block 302 of FIG. 3, the cell optimizer 130 may replace cell A 211 with replacement cell A4 311. Once the cell optimizer 130 replaces cell A 211 with cell A4 311, the path determiner 120 may again determine a timing of path 241 by measuring the new propagation time of a signal through path 241. If the new propagation time meets the timing criteria, then the path determiner 120 may determine that path 241 still includes a positive timing slack. If, however, the propagation time does not meet the timing criteria, then the path determiner 120 may determine that path 241 includes a timing violation, and may instruct the cell optimizer 130 to revert the cells in path 241 back to the previous state, that is, to replace cell A4 311 with cell A 211 after which the optimization of path 241 would be complete.

If with cell A4 311 in path 241, as shown in block 303 of FIG. 3, the timing of path 241 is determined to have a positive timing slack, the cell optimizer 130 may repeat the same optimization procedure for determining which cell to replace to achieve the lowest increase in timing delay per decrease in power leakage for path 241. For example, the cell optimizer 130 may determine that replacing cell B with replacement cell B6 would result in the lowest increase in timing delay per decrease in power leakage for path 241 based on the cost factors of replacing each of the cells 311, 212, 213 with their respective replacement cells. Continuing the optimization process, the path determiner 120 may again determine a timing of path 241 by measuring the new propagation time of a signal through path 241, and instruct the cell optimizer 130 either to continue optimizing the path or to revert to a previous cell configuration based on whether the propagation time meets the timing criteria.

In this manner, the apparatus 100 may optimize every path in the IC to have the most optimal power leakage while meeting timing criteria.

In an aspect, if initially, prior to any optimization of path 241, the path determiner 120 determines that the timing of path 241 does not meet the timing criteria, then path determiner 120 may instruct cell optimizer 130 to reduce the timing delay of path 241. The cell optimizer 130 may perform an optimization procedure for determining which cell in 241 to replace with which one of its replacement cells to achieve the greatest decrease in timing delay per increase in power leakage in path 241. For example, the cell optimizer 130 may determine that replacing cell B with replacement cell B4 would result in the greatest decrease in timing delay per increase in power leakage for path 241 based on the cost factors of replacing each of the cells 211, 212, 213 with their respective replacement cells. Continuing the optimization process, the path determiner 120 may again determine a timing of path 241 by measuring the new propagation time of a signal through path 241, and instruct the cell optimizer 130 either to continue optimizing the path to further reduce the timing delay to meet the timing criteria or to end the optimization if the timing criteria is met.

In an aspect, after path determiner 120 determines that the timing of path 241 meets the timing criteria, the cell optimizer 130 may determine whether the positive timing slack of path 241 is sufficient to accommodate a timing delay increase of an optimization that would provide the lowest increase in timing delay per decrease in power leakage for path 241. That is, the cell optimizer 130 may determine whether increasing the timing of path 241 by the optimized timing delay would prevent path 241 from meeting the timing criteria (e.g., whether optimized timing delay is greater than positive timing slack). If the cell optimizer 130 does determine that such an increase in timing would prevent path 241 from meeting the timing criteria, then the cell optimizer 130 may stop any further optimization of path 241, and may proceed to optimize a different path with the assistance of the path determiner 120.

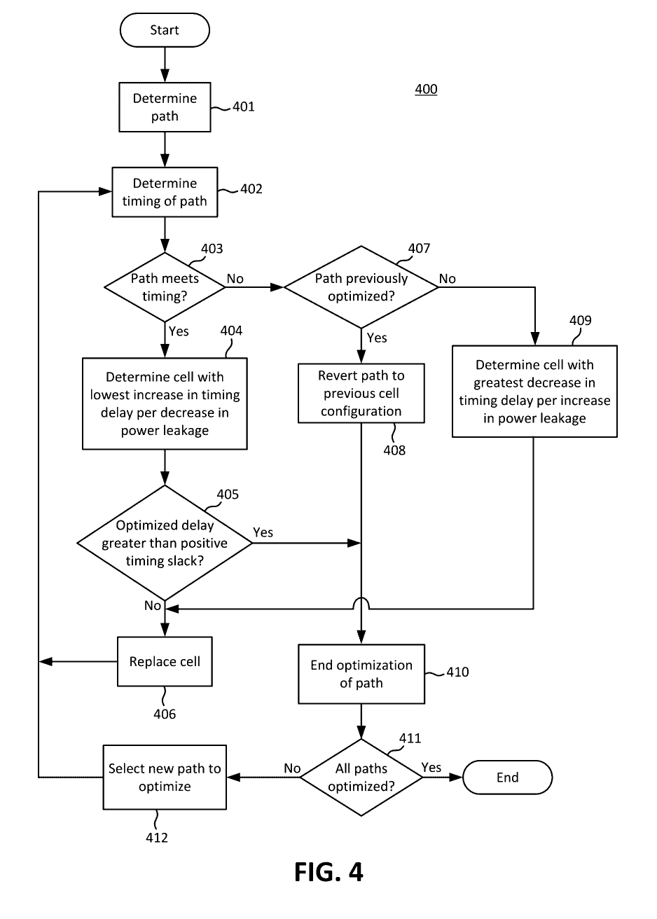

FIG. 4 is a flowchart conceptually illustrating an example of a method 400 of optimizing power leakage and timing delay in ICs based on a cost factor of replacing cells. Referring to FIG. 1, in an operational aspect, the apparatus 100 may perform various aspects of method 400. While, for purposes of simplicity of explanation, the method is shown and described as a series of acts, it is to be understood and appreciated that the method (and further methods related thereto) is/are not limited by the order of acts, as some acts may, in accordance with one or more aspects, occur in different orders and/or concurrently with other acts from that shown and described herein. For example, it is to be appreciated that a method could alternatively be represented as a series of interrelated states or events, such as in a state diagram. Moreover, not all illustrated acts may be required to implement a method in accordance with one or more features described herein. Moreover, it should be understood that the following actions or functions may be performed by a specially-programmed processor, a processor executing specially-programmed software or computer-readable media, or by any other combination of a hardware component and/or a software component capable of performing the described actions or functions.

In an aspect, at block 401, a path may be determined from a plurality of paths. For example, in one configuration, path determiner 120 may determine path 241 including cells 211, 212, 213 between first memory stage 201 and second memory stage 202. The method may then proceed to block 402.

At block 402, a timing of the path may be determined. For example, in one configuration, path determiner 120 may determine a timing of path 241 by measuring a propagation time of a signal through path 241. The method may then proceed to block 403.

At block 403, it is determined whether a timing of the path meets a timing criteria. For example, in an aspect, the path determiner 120 may determine whether the propagation time meets a timing criteria by comparing the propagation time to a time threshold. If the propagation time meets the timing criteria (i.e., propagation time is less than or equal to a time threshold), then the path determiner 120 may determine that the path includes a positive timing slack. If, however, the propagation time does not meet the timing criteria (i.e., propagation time is greater than the time threshold), then the path determiner 120 may determine that the path includes a timing violation. If it is determined that the timing of the path meets the timing criteria, then the method may proceed to block 404. If, on the other hand, it is determined that the timing of the path does not meet the timing criteria, then the method may proceed to block 407.

At block 404, a cell replacement providing the lowest increase in timing delay per decrease in power leakage for the path is determined. For example, in an aspect, the cell optimizer 130 may analyze each of the cells 211, 212, 213 individually with respect to each of their corresponding replacement cells, and determine which replacement cell would provide the lowest increase in timing delay per decrease in power leakage from among the replacement cells for each respective one of the cells 211, 212, 213. The cell optimizer 130 may perform this analysis by determining the cost factor for replacing each of the cells 211, 212, 213 with each one of their respective replacement cells. Once the cell optimizer 130 determines the most effective cost factor for each respective one of the cells 211, 212, 213, the cell optimizer may compare the cost factors, and select the cell associated with the cost factor having a lowest increase in timing delay per decrease in power leakage from among the cost factors associated with the cells 211, 212, 213. For example, the cell optimizer may determine that the cost factor with the lowest increase in timing delay per decrease in power leakage is the cost factor associated with replacing cell A 211 with replacement cell A4. The method may then proceed to block 405.

At block 405, it may be determined whether an optimized timing delay is greater than the positive timing slack of the path. For example, in an aspect, the cell optimizer 130 may determine whether increasing the timing of path 241 by the optimized timing delay would prevent path 241 from meeting the timing criteria. If so, then the method may proceed to block 410. If not, then the method may proceed to block 406.

At block 406, a cell in the path is replaced with the identified replacement cell. For example, in an aspect, the cell optimizer 130 may replace cell A 211 with replacement cell A4 311 to achieve the lowest increase in timing delay per decrease in power leakage for the path. Alternatively, as another example, the cell optimizer 130 may replace cell B 212 with replacement cell B4 to achieve the greatest decrease in timing delay per increase in power leakage for path 241 so as to attempt to meet a timing requirement. The method may then proceed back to block 402 to determine the timing of the path with the replacement cell.

At block 407, it may be determined whether a path that does not meet the timing criteria was previously optimized by having a cell replaced to achieve the lowest increase in timing delay per decrease in power leakage. For example, in an aspect, the path determiner 120 after determining that path 241 does not meet the timing criteria, may further determine whether the cell optimizer 130 had previously optimized path 241 to achieve the lowest increase in timing delay per decrease in power leakage. If it had, then the method may proceed to block 408, if it had not, then the method may proceed to block 409.

At block 409, a cell replacement providing the greatest decrease in timing delay per increase in power leakage for the path is determined. For example, in an aspect, the cell optimizer 130 may perform an optimization procedure for determining which cell in the path to replace with which of its replacement cells to achieve the greatest decrease in timing delay per increase in power leakage in path 241. For example, the cell optimizer 130 may determine that replacing cell B with replacement cell B4 would result in the greatest decrease in timing delay per increase in power leakage for path 241 based on the cost factors of replacing each of the cells 211, 212, 213 with their respective replacement cells. The method may then proceed to block 406.

At block 408, a cell configuration of a path is reverted to its previous cell configuration. For example, in an aspect, if the new propagation time of path 241 does not meet the timing criteria, and path 241 had been previously optimized (i.e., had a cell replaced to increase timing delay and decrease power leakage), then the cell optimizer 130 may revert the cells in path 241 back to the previous state. For example, after replacing cell A 211 with cell A4 311 during a prior optimization, and after having determined that with this new cell configuration path 241 does not meet the timing criteria, the cell optimizer 130 may revert path 241 back to its previous configuration by replacing cell A4 311 with cell A 211. The method may then proceed to block 410.

At block 410, the optimization of the path is terminated. For example, in an aspect, after the cell optimizer 130 reverts back to a previous cell configuration of path 241 in order to meet the timing criteria, the cell optimizer 130 may declare path 241 as being optimized and having an optimal timing delay and power leakage balance. Alternatively, as another example, if the cell optimizer 130 determines that increasing the timing of path 241 by a timing delay based on a cost factor would provide the lowest increase in timing delay per decrease in power leakage for the path, but would also result in such an increase in the timing of path 214 as to violate a timing requirement, then the cell optimizer 130 may declare path 241 as being optimized (i.e., having an optimal timing delay and power leakage balance). The method may then proceed to block 411.

At block 411, it may be determined whether all paths in the IC have been optimized. For example, in an aspect, the cell optimizer 130 may determine whether all paths in the IC have been optimized by determining whether there are any paths remaining in the IC that have not yet been declared as optimized by the cell optimizer 130. If the cell optimizer 130 determines that at least one path has not yet been optimized, then the method may proceed to block 412. Otherwise, the method ends.

At block 412, a new path is selected to be optimized. For example, in an aspect, the cell optimizer 130 may select a path that has not yet been declared as having been optimized. The method may then proceed to block 402 where, for example, the path determiner 120 may determine the timing of the new unoptimized path.

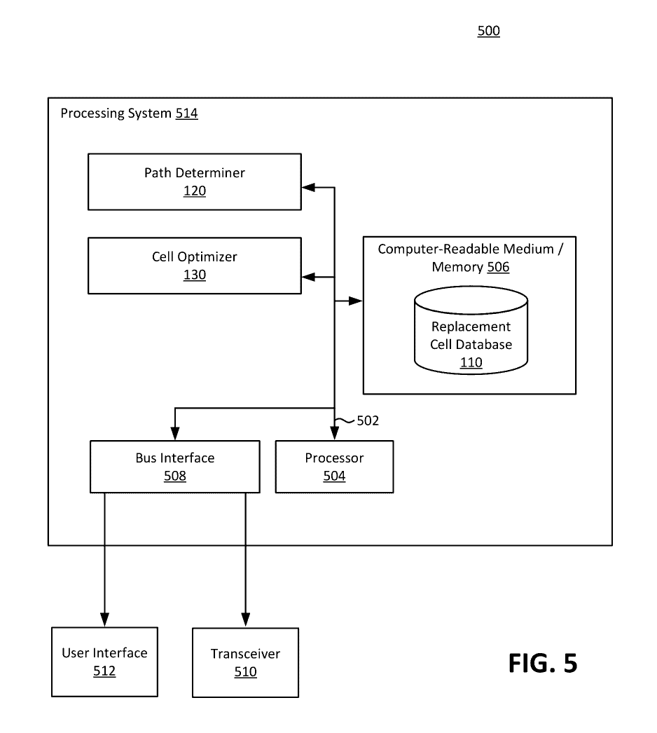

FIG. 5 is a conceptual diagram illustrating an example of a hardware implementation for an apparatus 500 employing a processing system 514 for optimizing power leakage and timing delay in ICs based on a cost factor of replacing cells. The apparatus 500 may correspond to the apparatus 100 of FIG. 1. In this example, the processing system 514 may be implemented with a bus architecture, represented generally by the bus 502. The bus 502 may include any number of interconnecting buses and bridges depending on the specific application of the processing system 514 and the overall design constraints. The bus 502 may link together various circuits including one or more processors, represented generally by the processor 504, and computer-readable media, represented generally by the computer-readable medium/memory 506. The bus 502 may also link a path determiner 120, a cell optimizer 130 to processor 504, and computer-readable medium/memory 506, which may include the replacement cell database 110. The bus 502 may also link various other circuits such as timing sources, peripherals, voltage regulators, and power management circuits, which are well known in the art, and therefore, will not be described any further. A bus interface 508 may provide an interface between the bus 502 and a transceiver 510. The transceiver 510 may provide a means for communicating with various other apparatus over a transmission medium. A user interface 512 (e.g., keypad, display, speaker, microphone, joystick) may also be provided.

The processor 504 is responsible for managing the bus 502 and general processing, including the execution of software stored on the computer-readable medium 506. The software, when executed by the processor 504, causes the processing system 514 to perform the various functions described infra for any particular apparatus. The computer-readable medium 506 may also be used for storing data that is manipulated by the processor 504 when executing software.

In an aspect, the path determiner 120 and the cell optimizer 130 may be implemented by software or computer-executable codes stored in computer-readable medium and executed on processor 504, and/or by processor modules within processor 504.

In one configuration, the apparatus (e.g., one or more of the components of the processing system 514) includes means for determining at least one path of a plurality of paths in a network of logic elements, the at least one path including a plurality of cells, each of the cells being configured to perform a logical operation. In addition, the apparatus includes means for identifying a cell of the plurality of cells based on a cost factor associated with replacing the cell with a replacement cell that performs the same logical operation, the cost factor being a function of a power leakage difference and a timing delay difference associated with the cell and the replacement cell. Furthermore, the apparatus includes means for replacing the cell with the replacement cell in the at least one path. The apparatus also includes means for determining a timing of the at least one path and determining whether a timing of the at least one path includes a positive timing slack or violates a timing criteria.

As described supra, an apparatus for optimizing power leakage and timing delay in ICs based on a cost factor of replacing cells is provided. Generally, when a path in an integrated circuit is determined to either have a positive timing slack or violate a timing constraint, an apparatus may identify a cell of a plurality of cells in the path based on a cost factor associated with replacing the cell with a replacement cell that performs the same logical operation. The cost factor may be a function of a power leakage difference and a timing delay difference associated with the cell and the replacement cell. Each of the plurality of cells may have associated therewith a set of replacement cells that perform the same logical operation and differ from one another based on at least one parameter. The set of replacement cells may also include an equivalent cell that has the same parameters as the corresponding one of the plurality of cells. The parameters may include a level of doping of a channel, a length of the channel, and a width of the channel. Each cell in the set of replacement cells may have associated therewith a cost factor for replacing the cell with another one of the cells in the set of replacement cells. If the apparatus determines that a timing of the at least one path includes a positive timing slack, the apparatus may determine a cost factor associated with replacing the cell with a replacement cell that has a lowest increase in timing delay per decrease in power leakage from among the cost factors associated with replacing other ones of the plurality of cells. On the other hand, if apparatus determines that the timing of the at least one path violates a timing criteria, the apparatus may determine a cost factor associated with replacing the cell with a replacement cell that has a greatest decrease in timing delay per increase in power leakage from among the cost factors associated with replacing other ones of the plurality of cell. The apparatus may perform multiple iterations of this optimization process until it determines that further optimizing the path would violate the timing constraint. Optimizing the paths in an IC in this manner is beneficial because it results in large power leakage reduction across the entire IC while maintaining a precise conformity with the timing requirement for all paths.

Further disclosure is included in the Appendix.

Several processors have been described in connection with various apparatuses and methods. These processors may be implemented using electronic hardware, computer software, or any combination thereof. Whether such processors are implemented as hardware or software will depend upon the particular application and overall design constraints imposed on the system. By way of example, a processor, any portion of a processor, or any combination of processors presented in this disclosure may be implemented with a microprocessor, microcontroller, digital signal processor (DSP), a field programmable gate array (FPGA), a programmable logic device (PLD), a state machine, gated logic, discrete hardware circuits, and other suitable processing component configured to perform the various functions described throughout this disclosure. The functionality of a processor, any portion of a processor, or any combination of processors presented in this disclosure may be implemented with software being executed by a microprocessor, microcontroller, DSP, or other suitable platform. Software shall be construed broadly to mean instructions, instruction sets, code, code segments, program code, programs, subprograms, software modules, applications, software applications, software packages, routines, subroutines, objects, executables, threads of execution, procedures, functions, etc., whether referred to as software, firmware, middleware, microcode, hardware description language, or otherwise. The software may reside on a computer-readable medium. A computer-readable medium may include, by way of example, memory such as a magnetic storage device (e.g., hard disk, floppy disk, magnetic strip), an optical disk (e.g., compact disk (CD), digital versatile disk (DVD)), a smart card, a flash memory device (e.g., card, stick, key drive), random access memory (RAM), read only memory (ROM), programmable ROM (PROM), erasable PROM (EPROM), electrically erasable PROM (EEPROM), a register, or a removable disk. Although memory is shown separate from the processors in the various embodiments presented throughout this disclosure, the memory may be internal to the processors (e.g., cache or register). A computer-readable medium may also include a carrier wave, a transmission line, or any other suitable medium for storing or transmitting software. Computer-readable medium may be embodied in a computer-program product. By way of example, a computer-program product may include a computer-readable medium in packaging materials. Those skilled in the art will recognize how best to implement the described functionality presented throughout this disclosure depending on the particular application and the overall design constraints imposed on the overall system.

It is understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover: a; b; c; a and b; a and c; b and c; and a, b and c. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. §112, sixth paragraph, unless the element is expressly recited using the phrase “means for” or, in the case of a method claim, the element is recited using the phrase “step for.”

What is claimed is:

1. A method of optimizing timing delay and power leakage in a circuit, comprising:
determining at least one path of a plurality of paths in a network of logic elements, the at least one path including a plurality of cells, each of the cells being configured to perform a logical operation;
identifying a first cell of the plurality of cells based on a first cost factor associated with replacing the first cell with a first replacement cell that performs the same logical operation, the first cost factor being a function of a power leakage difference and a timing delay difference associated with the first cell and the first replacement cell; and
replacing the first cell with the first replacement cell in the at least one path.

2. The method of claim 1, wherein each of the plurality of cells has associated therewith a set of replacement cells that perform the same logical operation and differ from one another based on at least one parameter, and wherein the set of replacement cells includes an equivalent cell that has the same parameters as the corresponding one of the plurality of cells.

3. The method of claim 2, wherein the at least one parameter is at least one of a level of doping of a channel, a length of the channel, and a width of the channel.

4. The method of claim 2, wherein each cell in the set of replacement cells has associated therewith a cost factor for replacing the cell with another one of the cells in the set of replacement cells.

5. The method of claim 4, further comprising:
determining that a timing of the at least one path includes a positive timing slack; and
wherein the first cost factor associated with replacing the first cell with the first replacement cell has a lowest increase in timing delay per decrease in power leakage from among the cost factors associated with replacing other ones of the plurality of cells.

6. The method of claim 4, further comprising:
determining that a timing of the at least one path violates a timing criteria; and
wherein the first cost factor associated with replacing the first cell with the first replacement cell has a greatest decrease in timing delay per increase in power leakage from among the cost factors associated with replacing other ones of the plurality of cells.

7. The method of claim 1, wherein:
the first cell has a power leakage p₁ and a timing delay d₁;
the first replacement cell has a power leakage p₂ and a timing delay d₂;
the power leakage difference is |p₁−p₂|;
the timing delay difference is |d₁−d₂|; and
the first cost factor associated with replacing the first cell with the first replacement cell is c₁, where c₁=|d₁−d₂|/|p₁−p₂|.

8. The method of claim 4, further comprising:
determining a timing of the at least one path after replacing the first cell with the first replacement cell;
determining whether the timing of the at least one path either includes a positive timing slack or violates a timing criteria.

9. The method of claim 8, wherein if the timing is determined to include the positive timing slack, the method further comprising:
identifying a second cell in the at least one path based on a second cost factor associated with replacing the second cell with a second replacement cell that performs the same logical operation, the second cost factor having a lowest increase in timing delay per decrease in power leakage from among the cost factors associated with replacing other cells in the at least one path.

10. The method of claim 8, wherein if the timing is determined to violate the timing criteria, the method further comprising:
identifying a second cell in the at least one path based on a second cost factor associated with replacing the second cell with a second replacement cell that performs the same logical operation, the second cost factor having a greatest decrease in timing delay per increase in power leakage from among the cost factors associated with replacing other cells in the at least one path.

11. An apparatus for optimizing timing delay and power leakage in a circuit, comprising:
means for determining at least one path of a plurality of paths in a network of logic elements, the at least one path including a plurality of cells, each of the cells being configured to perform a logical operation;
means for identifying a first cell of the plurality of cells based on a first cost factor associated with replacing the first cell with a first replacement cell that performs the same logical operation, the first cost factor being a function of a power leakage difference and a timing delay difference associated with the first cell and the first replacement cell; and
means for replacing the first cell with the first replacement cell in the at least one path.

12. The apparatus of claim 11, wherein each of the plurality of cells has associated therewith a set of replacement cells that perform the same logical operation and differ from one another based on at least one parameter, and wherein the set of replacement cells includes an equivalent cell that has the same parameters as the corresponding one of the plurality of cells.

13. The apparatus of claim 12, wherein the at least one parameter is at least one of a level of doping of a channel, a length of the channel, and a width of the channel.

14. The apparatus of claim 12, wherein each cell in the set of replacement cells has associated therewith a cost factor for replacing the cell with another one of the cells in the set of replacement cells.

15. The apparatus of claim 14, further comprising:
means for determining that a timing of the at least one path includes a positive timing slack; and
wherein the first cost factor associated with replacing the first cell with the first replacement cell has a lowest increase in timing delay per decrease in power leakage from among the cost factors associated with replacing other ones of the plurality of cells.

16. The apparatus of claim 14, further comprising:
means for determining that a timing of the at least one path violates a timing criteria; and
wherein the first cost factor associated with replacing the first cell with the first replacement cell has a greatest decrease in timing delay per increase in power leakage from among the cost factors associated with replacing other ones of the plurality of cells.

17. The apparatus of claim 11, wherein:
the first cell has a power leakage p₁ and a timing delay d₁;
the first replacement cell has a power leakage p₂ and a timing delay d₂;
the power leakage difference is |p₁−p₂|;
the timing delay difference is |d₁−d₂|; and
the first cost factor associated with replacing the first cell with the first replacement cell is c₁, where c₁=|d₁−d₂|/|p₁−p₂|.

18. The apparatus of claim 14, further comprising:
means for determining a timing of the at least one path after replacing the first cell with the first replacement cell;
means for determining whether the timing of the at least one path either includes a positive timing slack or violates a timing criteria.

19. The apparatus of claim 18, wherein if the timing is determined to include the positive timing slack, the method further comprising:
means for identifying a second cell in the at least one path based on a second cost factor associated with replacing the second cell with a second replacement cell that performs the same logical operation, the second cost factor having a lowest increase in timing delay per decrease in power leakage from among the cost factors associated with replacing other cells in the at least one path.

20. The apparatus of claim 18, wherein if the timing is determined to violate the timing criteria, the method further comprising:
means for identifying a second cell in the at least one path based on a second cost factor associated with replacing the second cell with a second replacement cell that performs the same logical operation, the second cost factor having a greatest decrease in timing delay per increase in power leakage from among the cost factors associated with replacing other cells in the at least one path.

21. An apparatus for optimizing timing delay and power leakage in a circuit, comprising:
a memory; and
at least one processor coupled to the memory and configured to:
determine at least one path of a plurality of paths in a network of logic elements, the at least one path including a plurality of cells, each of the cells being configured to perform a logical operation;
identify a first cell of the plurality of cells based on a first cost factor associated with replacing the first cell with a first replacement cell that performs the same logical operation, the first cost factor being a function of a power leakage difference and a timing delay difference associated with the first cell and the first replacement cell; and
replace the first cell with the first replacement cell in the at least one path.

22. The apparatus of claim 21, wherein each of the plurality of cells has associated therewith a set of replacement cells that perform the same logical operation and differ from one another based on at least one parameter, and wherein the set of replacement cells includes an equivalent cell that has the same parameters as the corresponding one of the plurality of cells.

23. The apparatus of claim 22, wherein the at least one parameter is at least one of a level of doping of a channel, a length of the channel, and a width of the channel.

24. The apparatus of claim 22, wherein each cell in the set of replacement cells has associated therewith a cost factor for replacing the cell with another one of the cells in the set of replacement cells.

25. The apparatus of claim 24, further comprising:
determining that a timing of the at least one path includes a positive timing slack; and
wherein the first cost factor associated with replacing the first cell with the first replacement cell has a lowest increase in timing delay per decrease in power leakage from among the cost factors associated with replacing other ones of the plurality of cells.

26. The apparatus of claim 24, wherein the at least one processor is further configured to:
determine that a timing of the at least one path violates a timing criteria; and
wherein the first cost factor associated with replacing the first cell with the first replacement cell has a greatest decrease in timing delay per increase in power leakage from among the cost factors associated with replacing other ones of the plurality of cells.

27. The apparatus of claim 21, wherein:
the first cell has a power leakage p₁ and a timing delay d₁;
the first replacement cell has a power leakage p₂ and a timing delay d₂;
the power leakage difference is |p₁−p₂|;
the timing delay difference is |d₁−d₂|; and
the first cost factor associated with replacing the first cell with the first replacement cell is c₁, where c₁=|d₁−d₂|/|p₁−p₂|.

28. The apparatus of claim 24, wherein the at least one processor is further configured to:
determine a timing of the at least one path after replacing the first cell with the first replacement cell;
determine whether the timing of the at least one path either includes a positive timing slack or violates a timing criteria.

29. The apparatus of claim 28, wherein if the timing is determined to include the positive timing slack, the at least one processor is further configured to:
identify a second cell in the at least one path based on a second cost factor associated with replacing the second cell with a second replacement cell that performs the same logical operation, the second cost factor having a lowest increase in timing delay per decrease in power leakage from among the cost factors associated with replacing other cells in the at least one path.

30. The apparatus of claim 28, wherein if the timing is determined to violate the timing criteria, the at least one processor is further configured to:
identify a second cell in the at least one path based on a second cost factor associated with replacing the second cell with a second replacement cell that performs the same logical operation, the second cost factor having a greatest decrease in timing delay per increase in power leakage from among the cost factors associated with replacing other cells in the at least one path.

31. A non-transitory computer-readable medium for optimizing timing delay and power leakage in a circuit, comprising code executable by a computer to:
determine at least one path of a plurality of paths in a network of logic elements, the at least one path including a plurality of cells, each of the cells being configured to perform a logical operation;
identify a first cell of the plurality of cells based on a first cost factor associated with replacing the first cell with a first replacement cell that performs the same logical operation, the first cost factor being a function of a power leakage difference and a timing delay difference associated with the first cell and the first replacement cell; and
replace the first cell with the first replacement cell in the at least one path.
